(19) United States
(12) Patent Application Publication
(10) Pub. No.: US 2024/0339967 A1
(43) Pub. Date: Oct. 10, 2024

(54) SEMICONDUCTOR AMPLIFIER CIRCUIT

(71) Applicant: Sumitomo Electric Device Innovations, Inc., Yokohama-shi (JP)

(72) Inventor: Akio OYA, Yokohama-shi (JP)

(73) Assignee: Sumitomo Electric Device Innovations, Inc., Yokohama-shi (JP)

(21) Appl. No.: 18/625,654

(22) Filed: Apr. 3, 2024

(30) Foreign Application Priority Data
Apr. 5, 2023 (JP) 2023-061231

(51) Int. Cl. H03F 3/04; H03F 1/56

(52) U.S. Cl. CPC H03F 3/04; H03F 1/565; H03F 2200/222

(57) ABSTRACT

A semiconductor amplifier circuit includes: a circuit board; a pre-stage amplifier including first and second transistors arranged side by side on the circuit board with a first reference line interposed therebetween; a post-stage amplifier disposed on the circuit board; and an inter-stage circuit formed on the circuit board, in which the inter-stage circuit includes: a phase adjustment line; an internal terminal; and a matching circuit, a first end of the phase adjustment line is connected to the output terminal, and a second end of the phase adjustment line is connected to the internal terminal, an input terminal of the matching circuit is connected to the internal terminal, and an output terminal of the matching circuit is connected to an input terminal of the post-stage amplifier, the first end and the second end are arranged on the first reference line, and the phase adjustment line has a line-symmetric shape.

### CROSS-REFERENCE TO RELATED APPLICATION

This application claims priority from Japanese Patent Application No. 2023-061231, filed on Apr. 5, 2023, the entire subject matter of which is incorporated herein by reference.

### TECHNICAL FIELD

The present disclosure relates to a semiconductor device.

### BACKGROUND

Japanese Unexamined Patent Publication No. H11-177356 describes an amplifier circuit including two-stage transistors. The amplifier circuit includes a power divider for performing impedance matching between a pre-stage transistor and a post-stage transistor.

### SUMMARY

A semiconductor amplifier circuit according to one aspect of the present disclosure includes: a circuit board; a pre-stage amplifier including a first transistor and a second transistor arranged side by side on the circuit board with a first reference line interposed therebetween, and amplifying an input signal to output an amplified signal from an output terminal on the first reference line; a post-stage amplifier disposed away from an output terminal of the pre-stage amplifier on the circuit board and further amplifying the amplified signal output from the output terminal; and an inter-stage circuit formed on the circuit board and propagating the amplified signal output from the output terminal of the pre-stage amplifier toward the post-stage amplifier, in which the inter-stage circuit includes: a phase adjustment line; an internal terminal; and a matching circuit configured to perform impedance matching between the pre-stage amplifier and the post-stage amplifier, a first end of the phase adjustment line is connected to the output terminal, and a second end opposite to the first end of the phase adjustment line is connected to the internal terminal, an input terminal of the matching circuit is connected to the internal terminal, and an output terminal of the matching circuit is connected to an input terminal of the post-stage amplifier, the first end and the second end are arranged on the first reference line, and the phase adjustment line has a line-symmetric shape with respect to the first reference line.

### BRIEF DESCRIPTION OF THE DRAWINGS

FIG. 1 is a plan view illustrating a configuration of a semiconductor amplifier circuit 1 according to an embodiment of the present disclosure;

FIG. 2 is a block diagram illustrating a schematic configuration of an amplifier circuit unit 3 of FIG. 1;

FIG. 3 is a circuit diagram illustrating a detailed circuit configuration of the amplifier circuit unit 3 of FIG. 1;

FIG. 4 is a plan view illustrating a configuration of a phase adjustment line 15 on a circuit board 2;

FIG. 5 is a graph illustrating a result of simulation calculation of frequency characteristics of output power (P5 dB);

FIG. 6 is a graph illustrating a result of simulation calculation of frequency characteristics of power added efficiency (PAE);

FIG. 7 is a circuit diagram illustrating a configuration of an amplifier circuit unit 903A according to a first comparative example; and

FIG. 8 is a circuit diagram illustrating a configuration of an amplifier circuit unit 903B according to a second comparative example.

### DETAILED DESCRIPTION

In a conventional amplifier circuit, it tends to be difficult to miniaturize a circuit that realizes wideband signal amplification.

An object of the present disclosure is to provide a semiconductor amplifier circuit capable of miniaturizing a wideband circuit.

In order to solve the above problems, a semiconductor amplifier circuit according to a first aspect of the present disclosure includes: a circuit board; a pre-stage amplifier including a first transistor and a second transistor arranged side by side on the circuit board with a first reference line interposed therebetween, and amplifying an input signal to output an amplified signal from an output terminal on the first reference line; a post-stage amplifier disposed away from an output terminal of the pre-stage amplifier on the circuit board and further amplifying the amplified signal output from the output terminal; and an inter-stage circuit formed on the circuit board and propagating the amplified signal output from the output terminal of the pre-stage amplifier toward the post-stage amplifier, in which the inter-stage circuit includes: a phase adjustment line; an internal terminal; and a matching circuit configured to perform impedance matching between the pre-stage amplifier and the post-stage amplifier, a first end of the phase adjustment line is connected to the output terminal, and a second end opposite to the first end of the phase adjustment line is connected to the internal terminal, an input terminal of the matching circuit is connected to the internal terminal, and an output terminal of the matching circuit is connected to an input terminal of the post-stage amplifier, the first end and the second end are arranged on the first reference line, and the phase adjustment line has a line-symmetric shape with respect to the first reference line.

The first aspect is the semiconductor amplifier circuit including: the pre-stage amplifier including the first transistor and the second transistor arranged on the circuit board with the first reference line interposed therebetween; the post-stage amplifier further amplifying the amplified signal output from the output terminal of the pre-stage amplifier; and the inter-stage circuit propagating the amplified signal from the pre-stage amplifier to the post-stage amplifier. Then, the phase adjustment line included in the inter-stage circuit has the first end connected to the output terminal of the pre-stage amplifier and the second end connected to the input terminal of the post-stage amplifier via the matching circuit, and has the line-symmetric shape with respect to the first reference line. With such a configuration, a length of the phase adjustment line can be easily adjusted without increasing a size of the semiconductor amplifier circuit including the circuit board. At the same time, a coupling capacitance generated between the first transistor and the phase adjustment line and a coupling capacitance generated between the second transistor and the phase adjustment line can be balanced. Thus, it is possible to reduce phase shift in amplified signals output from the first transistor and the second transistor, and to perform highly efficient signal amplification. As a result, the wideband circuit can be miniaturized.

In the semiconductor amplifier circuit according to a second aspect of the present disclosure, the phase adjustment line has a ring shape in the first aspect. In this case, the length of the phase adjustment line can be easily adjusted without increasing the size of the semiconductor amplifier circuit including the circuit board. As a result, the wideband circuit can be miniaturized.

Further, in the semiconductor amplifier circuit according to a third aspect of the present disclosure, the phase adjustment line includes: a first line formed along the first reference line; and a second line and a third line formed by branching in two directions away from the first reference line from the first line, in the first aspect or the second aspect. In this case, coupling capacitances generated between the second line and the third line and the pre-stage amplifier can be reduced, and highly efficient signal amplification can be realized.

Further, in the semiconductor amplifier circuit according to a fourth aspect of the present disclosure, the second line and the third line are formed to have a width of half a width of the first line in the third aspect. With such a configuration, the entire characteristic impedance of the phase adjustment line can be matched, and highly efficient signal amplification can be realized.

Further, in the semiconductor amplifier circuit according to a fifth aspect of the present disclosure, the second line and the third line are formed to branch in a direction perpendicular to the first reference line in the third aspect and the fourth aspect. In this case, the degree of freedom in adjusting the length of the phase adjustment line can be increased, and a usable frequency band can be easily expanded.

Further, in the semiconductor amplifier circuit according to a sixth aspect of the present disclosure, the second line and the third line are formed to have a line-symmetric shape with respect to a line perpendicular to the first reference line in any one of the third aspect to the fifth aspect. With such a configuration, the overall coupling capacitance including a coupling capacitance generated between the phase adjustment line and the pre-stage amplifier and a coupling capacitance generated between the phase adjustment line and the matching circuit can be reduced, and highly efficient signal amplification can be realized.

Further, in the semiconductor amplifier circuit according to a seventh aspect of the present disclosure, the second line and the third line are formed to have a rectangular shape line-symmetric with respect to the first reference line in the six aspect. In the case of such a configuration, the overall coupling capacitance including the coupling capacitance generated between the phase adjustment line and the pre-stage amplifier and the coupling capacitance generated between the phase adjustment line and the matching circuit can be reduced, and highly efficient signal amplification can be realized.

Furthermore, in the semiconductor amplifier circuit according to an eighth aspect of the present disclosure, a plurality of circuit units including the pre-stage amplifier, the post-stage amplifier, and the inter-stage circuit are arranged in parallel on the circuit board in any one of the first aspect to the seventh aspect. With such a configuration, the wideband circuit can be miniaturized.

Hereinafter, embodiments of the present disclosure will be described with reference to the drawings. Note that in description of the drawings, the same elements are denoted by the same reference signs, and redundant description will be omitted.

### (Configuration of Semiconductor Amplifier Circuit)

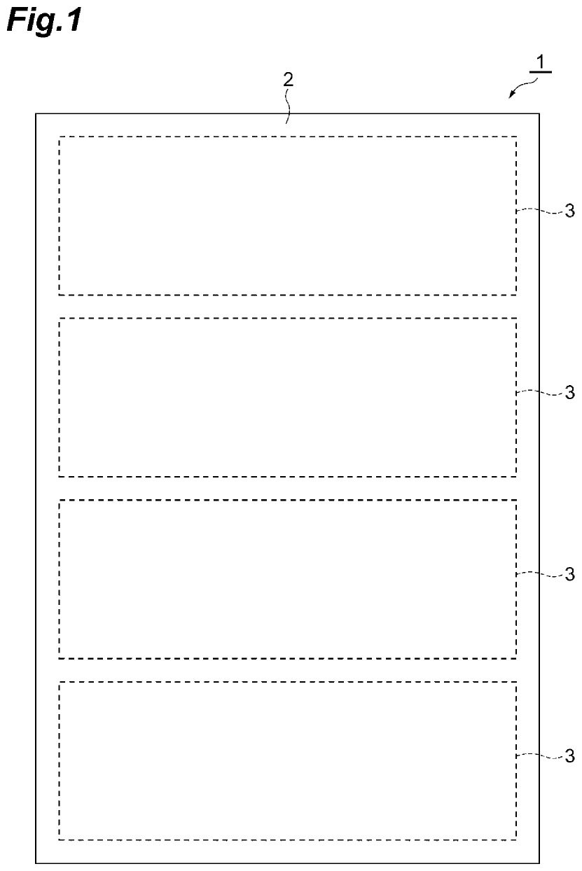

FIG. 1 is a plan view illustrating a configuration of a semiconductor amplifier circuit 1 according to an embodiment of the present disclosure. The semiconductor amplifier circuit 1 is a monolithic microwave integrated circuit (MMIC) that amplifies an analog signal.

As illustrated in FIG. 1, the semiconductor amplifier circuit 1 includes a circuit board 2 made of silicon carbide (SiC) or the like, and a plurality of amplifier circuit units 3 mounted on the circuit board 2. In the semiconductor amplifier circuit 1 of the present embodiment, four amplifier circuit units 3 are provided in parallel, but any number of amplifier circuit units 3 may be provided.

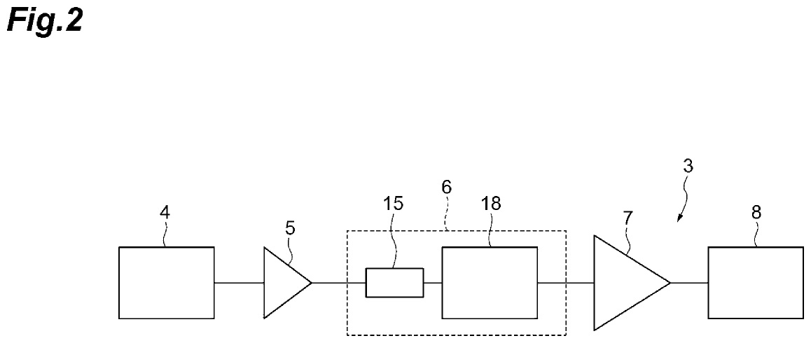

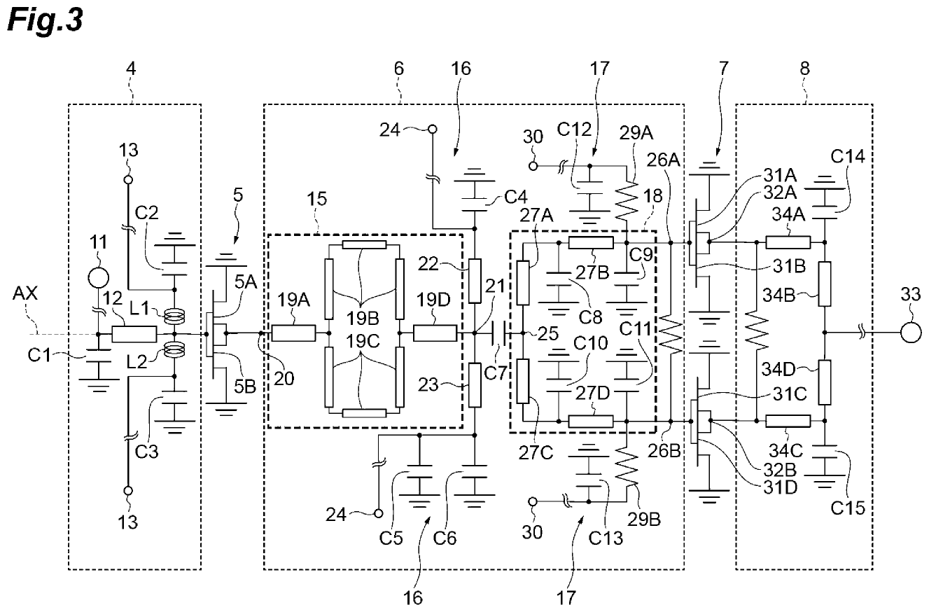

FIG. 2 is a block diagram illustrating a schematic configuration of the amplifier circuit unit 3, and FIG. 3 is a circuit diagram illustrating a detailed circuit configuration of the amplifier circuit unit 3.

As illustrated in FIG. 2, the amplifier circuit unit 3 includes an input matching circuit 4, a pre-stage amplifier 5, an inter-stage matching circuit (inter-stage circuit) 6, a post-stage amplifier 7, and an output matching circuit 8. A high frequency (RF) signal (An input signal) is externally input to the input matching circuit 4. The high frequency signal is, for example, an analog signal in a frequency range of 9.5 GHz or more and 13 GHz or less. The pre-stage amplifier 5 receives an input of the high frequency signal via the input matching circuit 4, and amplifies the high frequency signal to output the amplified signal. The amplified signal output from the pre-stage amplifier 5 is input to the post-stage amplifier 7 via the inter-stage matching circuit 6. The post-stage amplifier 7 further amplifies and outputs the input amplified signal. The amplified signal output from the post-stage amplifier 7 is output to the outside via the output matching circuit 8.

The circuit configuration of the amplifier circuit unit 3 will be described in detail with reference to FIG. 3.

The input matching circuit 4 includes capacitors C1, C2, and C3, inductors L1 and L2, and a wiring portion 12 that is a conductive line. A first end of two ends of the wiring portion 12 is connected to an input terminal 11 to which the high frequency signal is input, and is connected (grounded) to a reference potential line via the capacitor C1. A second end of the two ends of the wiring portion 12 is connected to an input of the pre-stage amplifier 5. The second end of the wiring portion 12 is connected to a bias input terminal 13 for supplying a gate bias to the pre-stage amplifier 5 via the inductor L1. Further, the second end of the wiring portion 12 is connected to the bias input terminal 13 for supplying the gate bias to the pre-stage amplifier 5 also via the inductor L2. The capacitors C2 and C3 are each connected between the bias input terminal 13 and the reference potential line.

The pre-stage amplifier 5 includes a first transistor 5A and a second transistor 5B. The first transistor 5A and the second transistor 5B are, for example, FETs. A gate terminal of the first transistor 5A and a gate terminal of the second transistor 5B constitute an input terminal of the pre-stage amplifier 5, and are connected to the input terminal 11 via the wiring portion 12 of the input matching circuit 4. A drain terminal of the first transistor 5A and a drain terminal of the second transistor 5B are connected to each other to constitute the output terminal of the pre-stage amplifier 5. A source terminal of the first transistor 5A and a source terminal of the second transistor 5B are each connected (grounded) to the reference potential line. The first transistor 5A and the second transistor 5B are arranged side by side on the circuit board 2 with a reference line (first reference line) AX extending along the wiring portion 12 interposed therebetween. That is, the input terminal and the output terminal of the pre-stage amplifier 5 are configured to be arranged on the reference line AX.

The inter-stage matching circuit 6 includes a phase adjustment line 15, bias circuits 16 and 17, and a matching circuit 18. The inter-stage matching circuit 6 is a circuit element that is formed on the circuit board 2 and propagates the amplified signal output from the output terminal of the pre-stage amplifier 5 toward the post-stage amplifier 7.

The phase adjustment line 15 includes a first line 19A, a second line 19B, a third line 19C, and a fourth line 19D, which are four conductive lines formed on the circuit board 2. The first line 19A is configured such that its first end is connected to a terminal 20 on the reference line AX connected to the output terminal of the pre-stage amplifier 5 and extends along the reference line AX. The fourth line 19D is separated from the first line 19A on the opposite side from the pre-stage amplifier 5 and formed to extend along the reference line AX. The second line 19B and the third line 19C are each formed to connect a second end of the first line 19A and a first end of the fourth line 19D close to the first line 19A. A second end of the fourth line 19D is connected to a terminal (an internal terminal) 21 on the reference line AX. The phase adjustment line 15 has a line-symmetric shape with respect to the reference line AX as a whole. Specifically, the second line 19B and the third line 19C of the phase adjustment line 15 are configured to form a rectangular ring shape that is line-symmetric with respect to the reference line AX.

The bias circuit 16 includes wiring portions 22 and 23 which are conductive lines on the circuit board 2, and capacitors C4, C5, and C6. The wiring portion 22 and the wiring portion 23 connect a bias input terminal 24 for supplying a drain bias to the pre-stage amplifier 5 and the terminal 21. The capacitors C4, C5, and C6 are connected between the bias input terminal 24 and the reference potential line.

The matching circuit 18 is a circuit that performs impedance matching between the pre-stage amplifier 5 and the post-stage amplifier 7. The matching circuit 18 includes one input terminal 25, two output terminals 26A and 26B, wiring portions 27A, 27B, 27C, and 27D which are conductive lines on the circuit board 2, and capacitors C8, C9, C10, and C11. The input terminal 25 is connected to the terminal 21 connected to the fourth line 19D of the phase adjustment line 15 via the capacitor C7. In addition, the input terminal 25 is connected to the output terminal 26A via the two wiring portions 27A and 27B, and is connected to the output terminal 26B via the two wiring portions 27C and 27D.

The capacitors C8 and C9 are respectively connected between two ends of the wiring portion 27B and the reference potential line, and the capacitors C10 and C11 are respectively connected between two ends of the wiring portion 27D and the reference potential line.

The bias circuit 17 includes resistive elements 29A and 29B and capacitors C12 and C13. The resistive element 29A and the resistive element 29B respectively connect a bias input terminal 30 for supplying the gate bias to the post-stage amplifier 7 and the two output terminals 26A and 26B. The capacitors C12 and C13 are connected between the bias input terminal 30 and the reference potential line.

The post-stage amplifier 7 is disposed on the circuit board 2 away from the output terminal of the pre-stage amplifier 5 in a direction along the reference line AX, receives the amplified signal output from the pre-stage amplifier 5 via the inter-stage matching circuit 6, and further amplifies the amplified signal. The post-stage amplifier 7 includes a first transistor 31A, a second transistor 31B, a third transistor 31C, and a fourth transistor 31D. The first transistor 31A, the second transistor 31B, the third transistor 31C, and the fourth transistor 31D are, for example, FETs. A gate terminal of the first transistor 31A and a gate terminal of the second transistor 31B constitute a first input terminal of the post-stage amplifier 7, and are connected to the output terminal 26A of the matching circuit 18. A drain terminal of the first transistor 31A and a drain terminal of the second transistor 31B are connected to each other to constitute a first output terminal 32A of the post-stage amplifier 7. A source terminal of the first transistor 31A and a source terminal of the second transistor 31B are each connected (grounded) to the reference potential line. A gate terminal of the third transistor 31C and a gate terminal of the fourth transistor 31D constitute a second input terminal of the post-stage amplifier 7, and are connected to the output terminal 26B of the matching circuit 18. A drain terminal of the third transistor 31C and a drain terminal of the fourth transistor 31D are connected to each other to constitute a second output terminal 32B of the post-stage amplifier 7. A source terminal of the third transistor 31C and a source terminal of the fourth transistor 31D are each connected (grounded) to the reference potential line.

The output matching circuit 8 is a circuit unit that synthesizes the amplified signals output from the two output terminals 32A and 32B of the post-stage amplifier 7 and propagates the synthesized amplified signals to an output terminal 33. The amplified signal synthesized at the output terminal 33 is output from the output terminal 33 to the outside. The output matching circuit 8 includes wiring portions 34A, 34B, 34C, and 34D, which are four conductive lines on the circuit board 2, and capacitors C14 and C15. The wiring portions 34A and 34B are formed to be connected in series between the output terminal 32A of the post-stage amplifier 7 and the output terminal 33. The wiring portions 34C and 34D are formed to be connected in series between the output terminal 32B of the post-stage amplifier 7 and the output terminal 33. The capacitor C14 is connected between a connection point between the two wiring portions 34A and 34B and the reference potential line. The capacitor C15 is connected between a connection point between the two wiring portions 34C and 34D and the reference potential line.

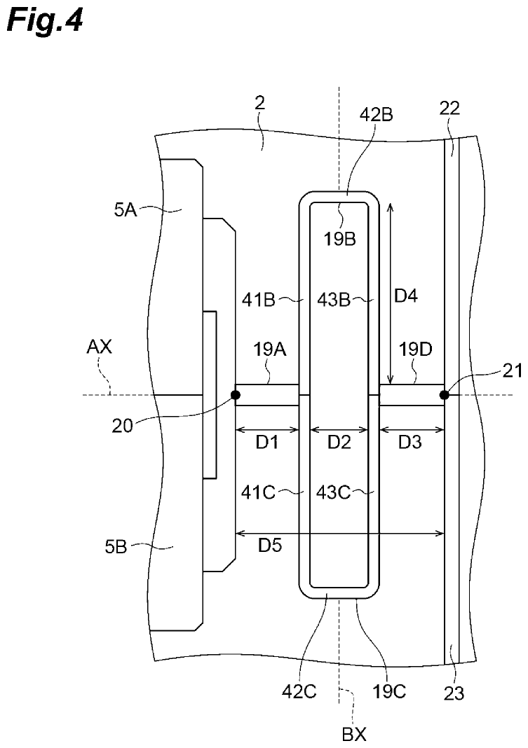

Here, a configuration of the phase adjustment line 15 of the inter-stage matching circuit 6 will be described in detail with reference to FIG. 4. FIG. 4 is a plan view illustrating the configuration of the phase adjustment line 15 on the circuit board 2.

The second line 19B and the third line 19C branch in two directions vertically away from the first line 19A along the reference line AX and respectively have straight line portions 41B and 41C extending in a direction perpendicular to the reference line AX. Further, the second line 19B and the third line 19C respectively further includes straight line portions 42B and 42C that are bent vertically from the straight line portions 41B and 41C and extend along the reference line AX, and straight line portions 43B and 43C that are bent vertically from the straight line portions 42B and 42C and extend to the first end of the fourth line 19D in the direction perpendicular to the reference line AX.

The first line 19A and the fourth line 19D have the same line width on the circuit board 2, and the second line 19B and the third line 19C as a whole have a line width of half a line width of the first line 19A on the circuit board 2. With such a configuration, the phase adjustment line 15 is configured to have a uniform characteristic impedance as a whole.

In addition, the first line 19A, the second line 19B, the third line 19C, and the fourth line 19D as a whole have a line-symmetric shape also with respect to a reference line BX perpendicular to the reference line AX along the circuit board 2. That is, the length of the first line 19A and the length of the fourth line 19D are the same, the lengths of the four straight portions 41B, 43B, 41C, and 43C are the same, and the lengths of the two straight portions 42B and 42C are the same.

A calculated line length of the phase adjustment line 15 having the above configuration is calculated as follows. Assuming that the length of the first line 19A is D1, the lengths of the straight line portions 42B and 42C are D2, the length of the fourth line 19D is D3, and the lengths of the straight line portions 41B, 43B, 41C, and 43C are D4, a calculated line length Lo is calculated by the following formula.

$$Lo = D 1 + ( D 4 \times 2 + D 2 ) / 2 + D 3$$

The semiconductor amplifier circuit 1 according to the present embodiment includes the plurality of amplifier circuit units 3 having the above-described configuration, and has a configuration in which a plurality of sets of the input matching circuit 4, the pre-stage amplifier 5, the inter-stage matching circuit (inter-stage circuit) 6, the post-stage amplifier 7, and the output matching circuit 8 are arranged in parallel on the circuit board 2.

### (Functions and Effects of Semiconductor Amplifier Circuit)

The semiconductor amplifier circuit 1 described above is a semiconductor amplifier circuit including: the pre-stage amplifier 5 including the first transistor 5A and the second transistor 5B arranged on the circuit board 2 with the reference line AX interposed therebetween; the post-stage amplifier 7 further amplifying the amplified signal output from the output terminal of the pre-stage amplifier 5; and the inter-stage matching circuit 6 propagating the amplified signal from the pre-stage amplifier 5 to the post-stage amplifier 7. Then, the phase adjustment line 15 included in the inter-stage matching circuit 6 has the first end connected to the output terminal of the pre-stage amplifier 5 and the second end connected to the input terminal of the post-stage amplifier 7 via the matching circuit 18, and has the line-symmetric shape with respect to the reference line AX. With such a configuration, the length of the phase adjustment line 15 can be easily adjusted without increasing the size of the semiconductor amplifier circuit 1 including the circuit board 2. At the same time, the coupling capacitance generated between the first transistor 5A and the phase adjustment line 15 and the coupling capacitance generated between the second transistor 5B and the phase adjustment line 15 can be balanced. Thus, it is possible to reduce the phase shift in the amplified signals output from the first transistor 5A and the second transistor 5B, and to perform highly efficient signal amplification.

For example, in order to achieve matching for sufficiently transmitting power from the pre-stage amplifier 5 to the post-stage amplifier 7 up to a low frequency band, it is necessary to increase the line length of the phase adjustment line 15. Even in such a case, the line length of the phase adjustment line 15 can be adjusted without enlarging the circuit board 2. In addition, as the line width of the phase adjustment line 15 is reduced narrower than a thickness of the circuit board 2, the coupling capacitance between the second line 19B of the phase adjustment line 15 and the first transistor 5A and the coupling capacitance between the third line 19C of the phase adjustment line 15 and the second transistor 5B cannot be ignored. In such a case, the amplified signal output from the first transistor 5A and the amplified signal output from the second transistor 5B are affected by the coupling capacitance, but since the phases of the two amplified signals output from the two transistors 5A and 5B are balanced, a decrease in the power of the amplified signal can be prevented. As a result, the wideband circuit can be miniaturized.

Further, in the semiconductor amplifier circuit 1, the phase adjustment line 15 includes rectangular ring-shaped lines 19B and 19C connected between the first line 19A and the fourth line 19D. In this case, the line length Lo of the phase adjustment line 15 can be easily adjusted without increasing the size of the semiconductor amplifier circuit 1 including the circuit board 2. In addition, the overall coupling capacitance including a coupling capacitance generated between the phase adjustment line 15 and the pre-stage amplifier 5 and a coupling capacitance generated between the phase adjustment line 15 and the wiring portions 22 and 23 can be reduced, and highly efficient signal amplification can be realized. As a result, the wideband circuit can be miniaturized.

For example, as the phase adjustment line 15, a configuration in which two lines drawn in parallel from the drain terminal of the first transistor 5A and the drain terminal of the second transistor 5B are provided, or a configuration in which two lines drawn in parallel from the terminal 20 are provided is also assumed. However, in this case, the line length Lo of the phase adjustment line 15 is shorter than that of the ring shape, and the degree of freedom in adjusting the line length Lo decreases. Further, as another configuration of the phase adjustment line 15, a configuration having a complicated shape such as a meander is also assumed. However, in this case, electromagnetic coupling between lines is strengthened, and the propagated amplified signal may be disturbed.

Further, in the semiconductor amplifier circuit 1, the phase adjustment line 15 includes: the first line 19A formed along the reference line AX; and the second line 19B and the third line 19C formed by branching from the first line 19A in directions perpendicular to the reference line AX. In this case, the coupling capacitances generated between the second line 19B and the third line 19C and the pre-stage amplifier 5 can be reduced, and highly efficient signal amplification can be realized. In addition, the degree of freedom in adjusting the line length Lo of the phase adjustment line 15 can be increased, and the usable frequency band can be easily expanded.

Further, in the semiconductor amplifier circuit 1, the second line 19B and the third line 19C are formed to have the line width of half the line width of the first line 19A. With such a configuration, the entire characteristic impedance of the phase adjustment line 15 can be matched, and highly efficient signal amplification can be realized.

Further, in the semiconductor amplifier circuit 1, the phase adjustment line 15 has a line-symmetric shape also with respect to the reference line BX. With such a configuration, the overall coupling capacitance including the coupling capacitance generated between the phase adjustment line 15 and the pre-stage amplifier 5 and the coupling capacitance generated between the phase adjustment line 15 and the wiring portions 22 and 23 can be reduced, and highly efficient signal amplification can be realized.

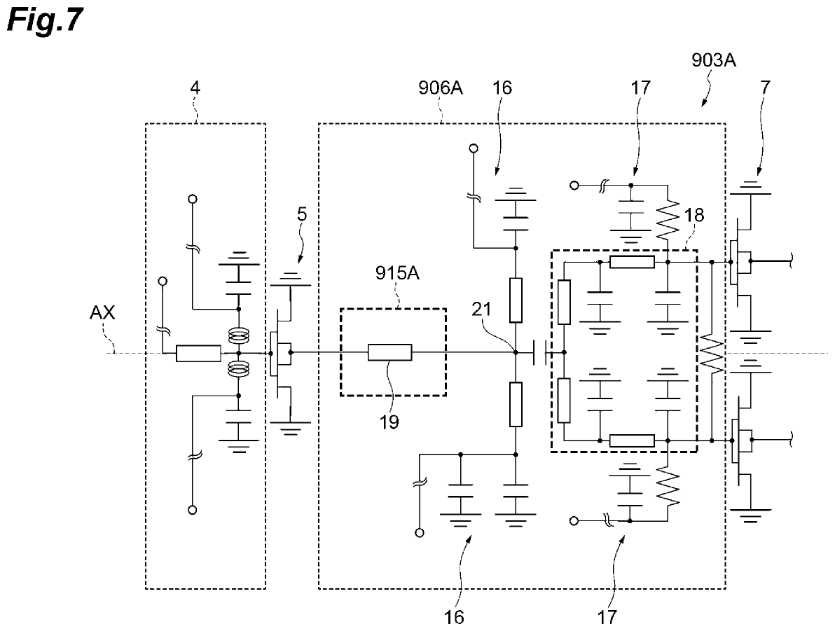

FIG. 7 illustrates a configuration of an amplifier circuit unit 903A according to a first comparative example. The amplifier circuit unit 903A includes a phase adjustment line 915A having a configuration different from that of the amplifier circuit unit 3. The phase adjustment line 915A includes a line 19 that is a linear conductive line formed on the circuit board 2. The line 19 is connected between the pre-stage amplifier 5 and the terminal 21. In such a configuration of the amplifier circuit unit 903A, in order to increase a line length of the phase adjustment line 915A, it is necessary to increase a size of the circuit board 2 in the direction along the reference line AX. Therefore, it is difficult to miniaturize the circuit in a case where it is desired to expand the usable frequency band to the low frequency band.

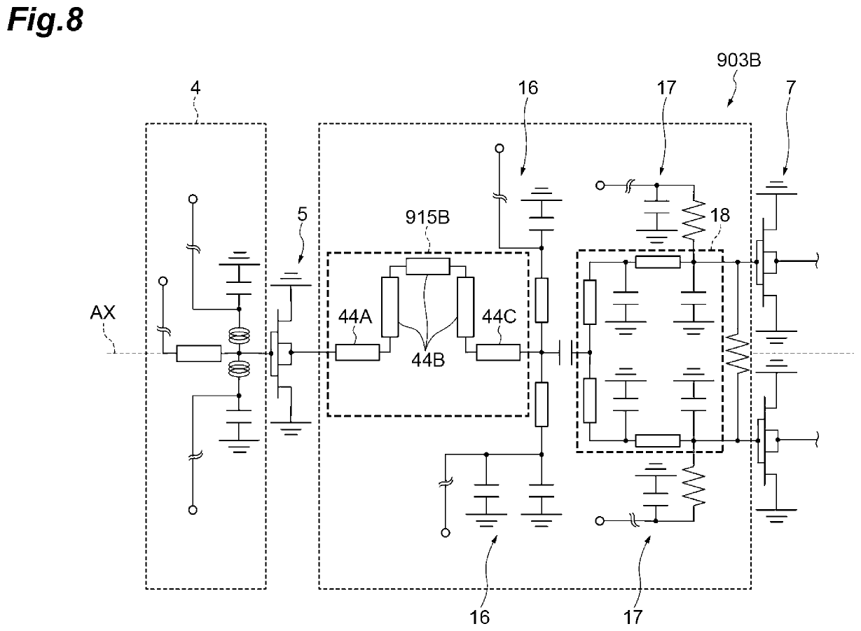

FIG. 8 illustrates a configuration of an amplifier circuit unit 903B according to a second comparative example. The amplifier circuit unit 903B includes a phase adjustment line 915B having a configuration different from that of the amplifier circuit unit 3. The phase adjustment line 915B includes a first line 44A, a second line 44B, and a third line 44C, which are three conductive lines formed on the circuit board 2. The first line 44A, the second line 44B, and the third line 44C are respectively formed to have the same shape as the first line 19A, the second line 19B, and the fourth line 19D of the phase adjustment line 15. However, the first line 44A, the second line 44B, and the third line 44C have the same line width on the circuit board 2. That is, the phase adjustment line 915B has an asymmetric shape with respect to the reference line AX. In such a configuration of the amplifier circuit unit 903B, a difference occurs between a coupling capacitance generated between the first transistor 5A and the phase adjustment line 915B and a coupling capacitance generated between the second transistor 5B and the phase adjustment line 915B. Therefore, the phase shift occurs in the amplified signals output from the first transistor 5A and the second transistor 5B, and the power of the output amplified signal may decrease.

Next, results of simulation calculation for demonstrating effects of the present embodiment will be described.

In the simulation calculation, in the amplifier circuit unit 3 according to the present embodiment, it is assumed that the circuit board 2 is a silicon carbide (SiC) substrate having a thickness of 100 μm, a ground layer (a reference potential layer) made of copper (Cu) is formed on a first surface (a surface opposite from a circuit mounting surface), and a conductive line including the phase adjustment line 15 is formed on a second surface (the circuit mounting surface) opposite from the first surface with a metal film made of copper (Cu) having a thickness of 4 μm. Furthermore, in the amplifier circuit unit 3 according to the present embodiment, it is assumed that the phase adjustment line 15 is formed such that the line widths of the first line 19A and the fourth line 19D are 30 μm, the lengths of the first line 19A and the fourth line 19D are D1=D3=72.5 μm, the line widths of the second line 19B and the third line 19C are 15 μm, and the lengths of the second line 19B and the third line 19C are D4=200 μm and D2=65 μm. That is, in the amplifier circuit unit 3 according to the present embodiment, it is assumed that the total length of the phase adjustment line 15 along the reference line AX is D5=240 μm and the line length Lo of the phase adjustment line 15 is 377.5 μm.

Further, in the simulation calculation, as “Comparative Example 1”, in the amplifier circuit unit 903A according to the first comparative example, the length of the line 19 of the phase adjustment line 915A is assumed to be 100 μm. Furthermore, as “Comparative Example 2”, in the amplifier circuit unit 903A according to the first comparative example, the length of the line 19 of the phase adjustment line 915A is assumed to be 240 μm, which is equal to the total length D5 of the phase adjustment line 15 in the present embodiment. Both of “Comparative Example 1” and “Comparative Example 2” are assumed to be the same as the present embodiment except for the configuration of the phase adjustment line 915A.

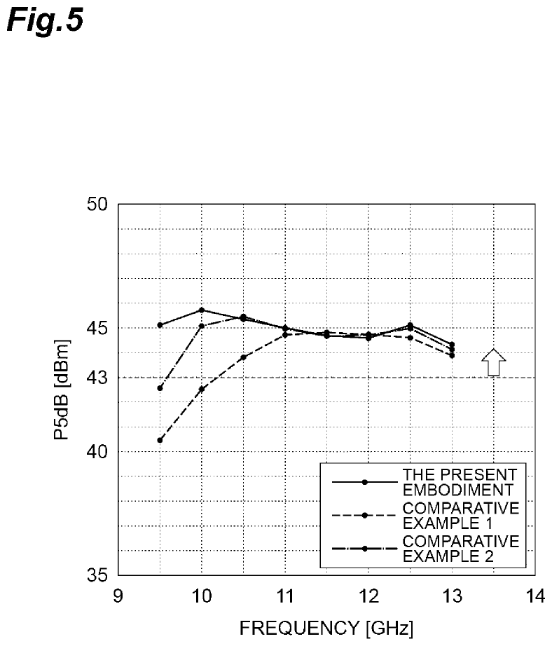

FIG. 5 is a graph illustrating a result of simulation calculation of frequency characteristics of output power (P5 dB) [dBm] at the time of 5 dB gain compression. From this result, in Comparative Example 1, it was found that the output power was below a target value of 43 dBm at a low frequency, that is, a frequency of 9.5 GHz or more and 10 GHz or less. In Comparative Example 2, as compared with Comparative Example 1, the frequency band in which the output power exceeds the target value is expanded, but it was found that the output power was below the target value at a frequency around 9.5 GHZ. In contrast, in the present embodiment, it was found that the output power sufficiently exceeded the target value in a frequency band of 9.5 GHz or more and 13 GHz or less.

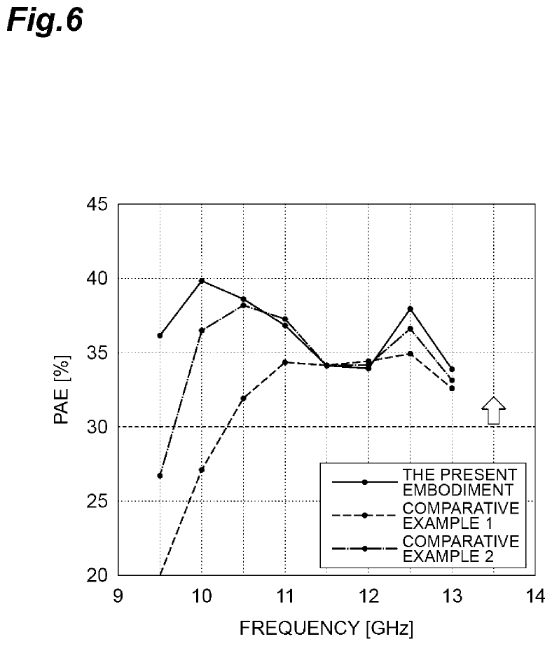

FIG. 6 is a graph illustrating a result of simulation calculation of frequency characteristics of power added efficiency (PAE) [%]. From this result, in Comparative Example 1, it was found that the power added efficiency was below the target value of 30% at a low frequency, that is, a frequency of 9.5 GHz or more and 10.5 GHz or less. In Comparative Example 2, as compared with Comparative Example 1, the frequency band in which the power added efficiency exceeds the target value is expanded, but it was found that the power added efficiency was below the target value at the frequency of 9.5 GHz or more and 10 GHz or less. In contrast, in the present embodiment, it was found that the power added efficiency sufficiently exceeded the target value in the frequency band of 9.5 GHz or more and 13 GHz or less.

Specifically, according to the above simulation calculation, in Comparative Example 2, the output power at the frequency of 9.5 GHz was calculated to be 42.6 dBm and the power added efficiency to be 26.7%. In contrast, in the present embodiment, it was found that the output power at a frequency of 9.5 GHz was improved by about 2.5 dB, and the power added efficiency was improved by about 9.4%.

Although the principles of the present disclosure have been illustrated and described above in the preferred embodiments, it is recognized by those skilled in the art that the present disclosure can be modified in arrangement and details without departing from such principles. The present disclosure is not limited to a specific configuration disclosed in the present embodiment. Accordingly, all modifications and changes coming from the scope of the claims and the spirit thereof are claimed.

What is claimed is:

1. A semiconductor amplifier circuit comprising:
a circuit board;
a pre-stage amplifier including a first transistor and a second transistor arranged side by side on the circuit board with a first reference line interposed therebetween, and amplifying an input signal to output an amplified signal from an output terminal on the first reference line;
a post-stage amplifier disposed away from an output terminal of the pre-stage amplifier on the circuit board and further amplifying the amplified signal output from the output terminal; and
an inter-stage circuit formed on the circuit board and propagating the amplified signal output from the output terminal of the pre-stage amplifier toward the post-stage amplifier, wherein
the inter-stage circuit includes:
a phase adjustment line;
an internal terminal; and
a matching circuit configured to perform impedance matching between the pre-stage amplifier and the post-stage amplifier,
a first end of the phase adjustment line is connected to the output terminal, and a second end opposite to the first end of the phase adjustment line is connected to the internal terminal,
an input terminal of the matching circuit is connected to the internal terminal, and an output terminal of the matching circuit is connected to an input terminal of the post-stage amplifier,
the first end and the second end are arranged on the first reference line, and the phase adjustment line has a line-symmetric shape with respect to the first reference line.

2. The semiconductor amplifier circuit according to claim 1, wherein the phase adjustment line has a ring shape.

3. The semiconductor amplifier circuit according to claim 1, wherein
the phase adjustment line includes:
a first line formed along the first reference line; and
a second line and a third line formed by branching in two directions away from the first reference line from the first line.

4. The semiconductor amplifier circuit according to claim 3, wherein the second line and the third line are formed to have a width of half a width of the first line.

5. The semiconductor amplifier circuit according to claim 3, wherein the second line and the third line are formed to branch in a direction perpendicular to the first reference line.

6. The semiconductor amplifier circuit according to claim 3, wherein the second line and the third line are formed to have a line-symmetric shape with respect to a line perpendicular to the first reference line.

7. The semiconductor amplifier circuit according to claim 6, wherein the second line and the third line are formed to have a rectangular shape line-symmetric with respect to the first reference line.

8. The semiconductor amplifier circuit according to claim 1, wherein a plurality of circuit units including the pre-stage amplifier, the post-stage amplifier, and the inter-stage circuit are arranged in parallel on the circuit board.
